(19) United States
(12) Patent Application Publication
(10) Pub. No.: US 2024/0276718 A1
(43) Pub. Date: Aug. 15, 2024

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventors: Rho Gyu KWAK, Icheon-si Gyeonggi-do (KR); Jung Shik JANG, Icheon-si Gyeonggi-do (KR); In Su PARK, Icheon-si Gyeonggi-do (KR); Seok Min CHOI, Icheon-si Gyeonggi-do (KR); Won Geun CHOI, Icheon-si Gyeonggi-do (KR); Jung Dal CHOI, Icheon-si Gyeonggi-do (KR)

(73) Assignee: SK hynix Inc., Icheon-si Gyeonggi-do (KR)

(21) Appl. No.: 18/333,251

(22) Filed: Jun. 12, 2023

(30) Foreign Application Priority Data
Feb. 13, 2023 (KR) 10-2023-0018940

(51) Int. Cl. H10B 43/27; H10B 41/27

(52) U.S. Cl. CPC H10B 43/27; H10B 41/27

(57) ABSTRACT

A semiconductor device includes a supporter including a plurality of stairs, a gate structure including gate lines that are stacked on the supporter, wherein the gate lines include pads, and the pads are disposed over the plurality of stairs, first contact plugs that are connected to the pads, and channel structures that extend through the gate structure.

### CROSS-REFERENCE TO RELATED APPLICATION

This application claims priority under 35 U.S.C. § 119(a) to Korean Patent Application No. 10-2023-0018940 filed on Feb. 13, 2023, in the Korean Intellectual Property Office, which is incorporated herein by reference in its entirety.

### BACKGROUND

### 1. Technical Field

Embodiments generally relate to an electronic device and a method of manufacturing an electronic device and, more particularly, to a semiconductor device and a method of manufacturing a semiconductor device.

### 2. Related Art

The degree of integration of semiconductor devices is basically determined by an area that is occupied by a unit memory cell. Recently, as the improvements of the degree of integration of semiconductor devices in which memory cells are formed on a substrate as a single layer reaches its limit, there is proposed a three-dimensional (3-D) semiconductor device in which memory cells are stacked on a substrate. Furthermore, in order to improve operation reliability of such a semiconductor device, various structures and manufacturing methods are being developed.

### SUMMARY

In an embodiment, a semiconductor device may include a supporter including a plurality of stairs, a gate structure including gate lines that are stacked on the supporter, wherein the gate lines include pads, respectively, and the pads are disposed over the plurality of stairs, respectively, first contact plugs that are connected to the pads, respectively, and channel structures that extend through the gate structure.

In an embodiment, a semiconductor device may include a first supporter including a plurality of first stairs, a second supporter disposed on the first supporter and including a plurality of second stairs, a first gate structure including first gate lines that are stacked on the first supporter, wherein the first gate lines include first pads, respectively, and the first pads are disposed over the first stairs, a second gate structure including second gate lines that are stacked on the second supporter, wherein the second gate lines include second pads, respectively, and the second pads are disposed over the second stairs, first contact plugs that extend through the second gate structure and that are connected to the first pads, respectively, and second contact plugs that are connected to the second pads, respectively.

In an embodiment, a method of manufacturing a semiconductor device may include forming a supporter including a plurality of stairs, forming a stack by alternately stacking first material layers and second material layers on the supporter, etching the stack so that each of the second material layers is exposed, forming third material layers including pads that are disposed over the plurality of stairs, respectively, by substituting the second material layers with the third material layers, and forming first contact plugs that are connected to the pads, respectively.

In an embodiment, a method of manufacturing a semiconductor device may include forming a first supporter including a plurality of first stairs, forming a first stack by alternately stacking first material layers and second material layers on the first stairs, etching the first stack so that each of the second material layers is exposed, forming, on the first supporter, a second supporter including a plurality of second stairs, forming a second stack by alternately stacking third material layers and fourth material layers on the second stairs, etching the second stack so that each of the fourth material layers is exposed, substituting the second material layers with fifth material layers, substituting the fourth material layers with sixth material layers, forming first contact plugs that are connected to first pads, respectively, wherein the fifth material layers include the first pads, respectively, and forming second contact plugs that are connected to second pads, respectively, wherein the sixth material layers include the second pads, respectively.

### BRIEF DESCRIPTION OF THE DRAWINGS

FIG. 1 is a diagram for describing a semiconductor device according to an embodiment of the present disclosure.

FIG. 2 is a diagram for describing a semiconductor device according to an embodiment of the present disclosure.

FIGS. 3A to 3D are diagrams for describing a method of manufacturing a semiconductor device according to an embodiment of the present disclosure.

FIGS. 4A to 4C are diagrams for describing a method of manufacturing a semiconductor device according to an embodiment of the present disclosure.

FIGS. 5A to 5E are diagrams for describing a method of manufacturing a semiconductor device according to an embodiment of the present disclosure.

### DETAILED DESCRIPTION

Hereinafter, embodiments according to the technical spirit of the present disclosure are described with reference to the accompanying drawings. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. It will be understood that although the terms first, second, third etc. may be used herein to describe various elements, these elements should not be limited by these terms. These terms are only used to distinguish one element from another element, but not used to define only the element itself or to mean a particular sequence.

An embodiment of the present disclosure may provide a semiconductor device having a stable structure and improved characteristics and a method of manufacturing a semiconductor device.

An embodiment of the present technology can provide the semiconductor device having a stable structure and having improved reliability.

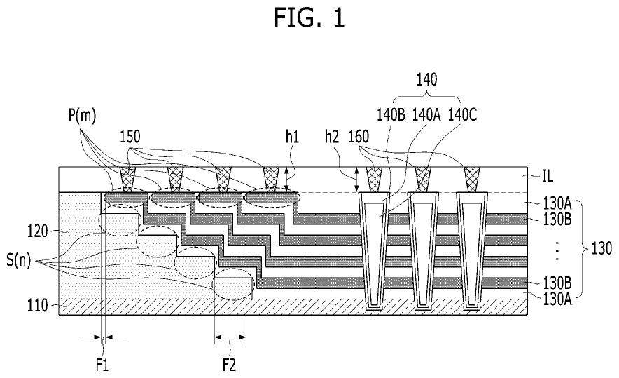

FIG. 1 is a diagram for describing a semiconductor device according to an embodiment of the present disclosure.

Referring to FIG. 1, the semiconductor device may include a substrate 110, a supporter 120, a gate structure 130, channel structures 140, first contact plugs 150, or second contact plugs 160 or may include the substrate 110, the supporter 120, the gate structure 130, the channel structures 140, the first contact plugs 150, or the second contact plugs 160 in combination. The semiconductor device may further include an interlayer insulating layer IL.

The supporter 120 may be disposed on the substrate 110. The supporter 120 may be disposed in some area of the substrate 110. The substrate 110 may be a semiconductor substrate, such as a silicon wafer, an SiGe wafer, or an SOI wafer. The supporter 120 may include a plurality of stairs S. For example, the supporter 120 may include ‘n’ stairs S. ‘n’ may be an integer equal to or greater than 2. The supporter 120 may include an insulating material or a conductive material or may include the insulating material or the conductive material in combination. For example, the supporter 120 may include an insulating material, such as oxide or nitride. For reference, the supporter 120 may be a part of the substrate 110.

The gate structure 130 may be disposed on the supporter 120. The gate structure 130 may be disposed on the supporter 120, and may extend along the substrate 110. The gate structure 130 may include insulating layers 130A and conductive layers 130B that are alternately stacked. The conductive layers 130B may be stacked on the supporter 120. The conductive layers 130B may include pads P, respectively. The pads P may be disposed on an upper surface of the gate structure 130. The pads P may be disposed substantially at the same level. The pads P may be disposed over the plurality of stairs S, respectively. The pads P may be disposed in accordance with the plurality of stairs S. The pad P and the stair S that correspond to each other may be disposed so that the edges of the pad P and the stair S are mutually aligned or offset. In this case, the degrees that the pads P are offset may be substantially the same or different from each other.

The conductive layer 130B that is disposed to be closer to the supporter 120 may have a smaller offset distance between the stair S and the pad P. As the number of conductive layers 130B that are stacked between the supporter 120 and the pad P is increased, the offset distance between the stair S and the pad P may be increased. For example, the conductive layer 130B that is stacked on a relatively lower part, among the conductive layers 130B, may be disposed to be closer to the supporter 120, and the stair S and the pad P related to the conductive layer 130B that is stacked on the relatively lower part may be offset by a first distance F1. The conductive layer 130B that is stacked on a relatively upper part, among the conductive layers 130B, may be disposed to be farther from the supporter 120, and the stair S and the pad P related to the conductive layer 130B that is stacked on the relatively upper part may be offset by a second distance F2 greater than the first distance F1.

The pads P may be ‘m’ in number. ‘m’ may be the same as or different from ‘n’ in number. For example, ‘m’ may be the same as ‘n’ in number. In other words, the number of pads P may be the same as or different from the number of stairs S. For example, the number of pads P may be the same as the number of stairs S. In this case, the heights of the stairs S may be substantially the same or different from each other. The heights of the stairs S may be determined by considering the thicknesses of the insulating layers 130A and the conductive layers 130B. For example, the height of each stair S may be substantially the same as the sum of thicknesses of a pair of the insulating layer 130A and the conductive layer 130B. The insulating layer 130A may include an insulating material, such as oxide. The conductive layer 130B may include a conductive material, such as tungsten. The conductive layer 130B may be a gate line, such as a word line, a bit line, or a selection line.

The channel structures 140 may extend through the gate structure 130. For example, the channel structures 140 may extend through the gate structure 130, and may be connected to the substrate 110. In this case, the substrate 110 may include a source structure or may include a source area that is doped with impurities. Upper surfaces of the channel structures 140 may be disposed substantially at the same level as the upper surface of the gate structure 130. For example, the upper surfaces of the channel structures 140 may be disposed substantially at the same level as upper surfaces of the pads P.

The channel structures 140 may each include a channel layer 140A. The channel structures 140 may each include a memory layer 140B that surrounds the channel layer 140A or an insulating core 140C within the channel layer 140A or may each include the memory layer 140B or the insulating core 140C in combination. In this case, the channel layer 140A may be connected to the substrate 110. For example, a source layer of the source structure may be directly connected to the channel layer 140A. Alternatively, an epitaxial pattern may be formed on the substrate 110. The channel layer 140A and the substrate 110 may be connected through the epitaxial pattern. The channel layer 140A may include a semiconductor material, such as silicon or germanium. The memory layer 140B may include a blocking layer, a data storage layer, or a tunneling layer or may include the blocking layer, the data storage layer, or the tunneling layer in combination. The insulating core 140C may include an insulating material, such as oxide, nitride, or a gap (i.e., an air gap).

The first contact plugs 150 may be disposed on the gate structure 130. The first contact plugs 150 may extend through the interlayer insulating layer IL, and may be connected to the conductive layers 130B. For example, the first contact plugs 150 may be connected to the pads P, respectively. The interlayer insulating layer IL may be disposed on the gate structure 130. The first contact plugs 150 may each have a first height “h1”. The first heights “h1” of the first contact plugs 150 may be substantially the same because the first contact plugs 150 are disposed on the pads P that are disposed substantially at the same level. In an embodiment, because the pads P are disposed on the upper surface of the gate structure 130, the aspect ratio of the first contact plugs 150 can be reduced. Accordingly, in an embodiment, a failure in a process, which occurs when the first contact plugs having a great aspect ratio are formed, can be prevented or reduced.

The second contact plugs 160 may be disposed on the gate structure 130. The second contact plugs 160 may extend through the interlayer insulating layer IL, and may be connected to the channel structures 140, respectively. The second contact plugs 160 may each have a second height “h2”. The second height “h2” of the second contact plug 160 may be substantially the same as or different from the first height “h1”. For example, the second height “h2” of the second contact plug 160 may be substantially the same as the first height “h1” of the first contact plug 150. Accordingly, the second contact plugs 160 may be formed simultaneously with the first contact plugs 150. The second contact plugs 160 may include a conductive material, such as tungsten. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

According to the aforementioned structure, the pads P may be disposed on the supporter 120 that includes the plurality of stairs S. Accordingly, the pads P may be disposed substantially at the same level. Furthermore, the first contact plugs 150 that are connected to the pads P may have substantially the same height. Accordingly, in an embodiment, the aspect ratio of the first contact plugs 150 can be reduced because the pads P are disposed on the upper surface of the gate structure 130.

The semiconductor device may have a structure in which a cell chip including a cell array and a peripheral circuit chip including a peripheral circuit have been bonded. In such a case, the substrate 110, the supporter 120, the gate structure 130, the channel structures 140, the first contact plugs 150, or the second contact plugs 160, which have been described with reference to FIG. 1, may be included in the cell chip. Furthermore, in an embodiment, an interconnection structure for electrically connecting the cell chip and the peripheral circuit chip can be improved by disposing the pads P substantially at the same height and reducing the aspect ratio of the first contact plugs 150.

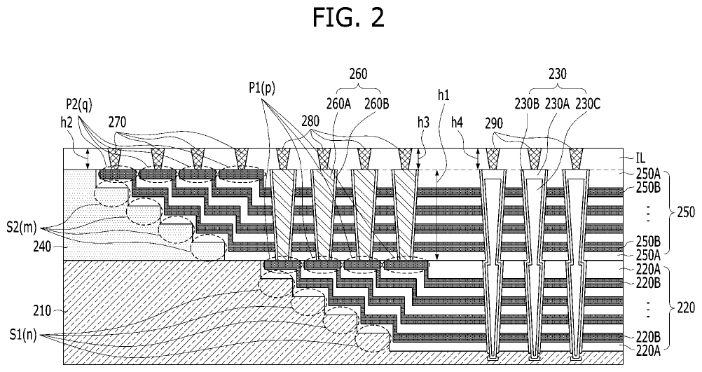

FIG. 2 is a diagram for describing a semiconductor device according to an embodiment of the present disclosure. Hereinafter, contents that are redundant with the aforementioned contents are omitted and not described.

Referring to FIG. 2, the semiconductor device may include a first supporter 210, a first gate structure 220, channel structures 230, a second supporter 240, a second gate structure 250, first contact plugs 260, second contact plugs 270, third contact plugs 280, or fourth contact plugs 290 or may include the first supporter 210, the first gate structure 220, the channel structures 230, the second supporter 240, the second gate structure 250, the first contact plugs 260, the second contact plugs 270, the third contact plugs 280, or the fourth contact plugs 290 in combination. The semiconductor device may further include an interlayer insulating layer IL.

The first supporter 210 may be a part of a substrate. For example, the first supporter 210 may be formed by etching the substrate. In this case, the substrate may include a source structure, and may include a source area doped with impurities. The first supporter 210 may include a plurality of first stairs S1. For example, the first supporter 210 may include ‘n’ first stairs S1. In this case, ‘n’ may be an integer equal to or greater than 2. The first supporter 210 may be a semiconductor substrate, such as a silicon wafer, an SiGe wafer, or an SOI wafer, but the present disclosure is not limited thereto. The first supporter 210 may include an insulating material or a conductive material or may include the insulating material or the conductive material in combination.

The second supporter 240 may be disposed on the first supporter 210. The second supporter 240 may include a plurality of second stairs S2. For example, the second supporter 240 may include ‘m’ second stairs S2. In this case, m may be an integer equal to or greater than 2. The second supporter 240 may include an insulating material or a conductive material or may include the insulating material or the conductive material in combination. For example, the second supporter 240 may include oxide.

The first gate structure 220 may be disposed on the first supporter 210. The first gate structure 220 may include first insulating layers 220A and first conductive layers 220B that are alternately stacked. The first conductive layers 220B may be stacked over the first supporter 210. The first conductive layers 220B may include first pads P1, respectively. The first pads P1 may be disposed on an upper surface of the first gate structure 220. The first pads P1 may be disposed over the plurality of first stairs S1, respectively. The first pads P1 may be disposed substantially at the same level. The first pads P1 may be disposed in accordance with the plurality of first stairs S1, and may be disposed by being offset by the number of layers that are stacked between the first pads P1 and the first stairs S1. The first pads P1 may be ‘p’ in number. ‘p’ may be substantially the same as or different from ‘n’ in number. For example, ‘p’ may be the same as ‘n’ in number. In other words, the number of first pads P1 may be the same as or different from the number of first stairs S1. For example, the number of first pads P1 may be the same as the number of first stairs S1.

The second gate structure 250 may be disposed on the second supporter 240. The second gate structure 250 may include second insulating layers 250A and second conductive layers 250B that are alternately stacked. The second conductive layers 250B may be stacked over the second supporter 240. The second conductive layers 250B may include second pads P2, respectively. The second pads P2 may be disposed on an upper surface of the second gate structure 250. The second pads P2 may be disposed over the plurality of second stairs S2, respectively. The second pads P2 may be disposed substantially at the same level. The second pads P2 may be disposed in accordance with the plurality of second stairs S2, and may be disposed by being offset by the number of layers that are stacked between the second pads P2 and the second stairs S2. The second pads P2 may be ‘q’ in number. ‘q’ may be substantially the same as or different from ‘m’ in number. For example, ‘q’ may be the same as ‘m’ in number. In other words, the number of second pads P2 may be the same as or different from the number of second stairs S2. For example, the number of second pads P2 may be the same as the number of second stairs S2.

The channel structures 230 may extend through the second gate structure 250 and the first gate structure 220. For example, the channel structures 230 may extend through the second gate structure 250 and the first gate structure 220, and may be connected to the first supporter 210. Upper surfaces of the channel structures 230 may be disposed substantially at the same level as the upper surface of the second gate structure 250. For example, the upper surfaces of the channel structures 230 may be disposed substantially at the same level as upper surfaces of the second pads P2. The channel structures 230 may each include a channel layer 230A, a memory layer 230B, or an insulating core 230C or may each include the channel layer 230A, the memory layer 230B, or the insulating core 230C in combination.

The first contact plugs 260 may each include a conductive plug 260A or an insulating spacer 260B that surrounds the sidewall of the conductive plug 260A or may each include the conductive plug 260A or the insulating spacer 260B in combination. The first contact plugs 260 may be disposed on the first gate structure 220, may extend through the second gate structure 250, and may be connected to the first conductive layers 220B. For example, the first contact plugs 260 may extend through the second gate structure 250, and may be connected to the first pads P1. Upper surfaces of the first contact plugs 260 may be disposed substantially at the same level as the upper surfaces of the second pads P2. The first contact plugs 260 may be disposed between the second pads P2 and the channel structures 230. The conductive plugs 260A may be electrically connected to the first pads P1. In an embodiment, the insulating spacer 260B may be for preventing the second conductive layers 250B and the conductive plug 260A from being electrically connected.

The first contact plugs 260 may each have a first height “h1”. The first heights “h1” of the first contact plugs 260 may be substantially the same because the first contact plugs 260 are disposed on the first pads P1 that are disposed substantially at the same level. In an embodiment, the aspect ratio of the first contact plugs 260 can be reduced because the first pads P1 are disposed on the upper surface of the first gate structure 220. Accordingly, in an embodiment, a failure in a process, which occurs when the first contact plugs having a great aspect ratio are formed, can be prevented or reduced. The conductive plug 260A may include a conductive material, such as tungsten. The insulating spacer 260B may include an insulating material, such as oxide, nitride, or an air gap.

The second contact plugs 270 may be disposed on the second gate structure 250. The second contact plugs 270 may extend through the interlayer insulating layer IL, and may be connected to the second conductive layers 250B. For example, the second contact plugs 270 may be connected to the second pads P2, respectively. The second contact plugs 270 may each have a second height “h2”. The second heights “h2” of the second contact plugs 270 may be substantially the same because the second contact plugs 270 are disposed on the second pads P2 that are disposed substantially at the same level. In an embodiment, the aspect ratio of the second contact plugs 270 can be reduced because the second pads P2 are disposed on the upper surface of the second gate structure 250. Accordingly, in an embodiment, a failure in a process, which occurs when the second contact plugs having a great aspect ratio are formed, can be prevented or reduced. The second contact plugs 270 may include a conductive material, such as tungsten.

The third contact plugs 280 may be disposed on the second gate structure 250. The third contact plugs 280 may be connected to the first contact plugs 260, respectively. For example, the third contact plugs 280 may extend through the interlayer insulating layer IL, and may be connected to the first contact plugs 260, respectively. The third contact plugs 280 may each have a third height “h3”. The third heights “h3” of the third contact plugs 280 may be substantially the same. Furthermore, the second height “h2” and the third height “h3” may be substantially the same or different from each other. For example, the second height “h2” may be substantially the same as the third height “h3”. Accordingly, the third contact plugs 280 may be formed when the second contact plugs 270 are formed. The third contact plugs 280 may include a conductive material, such as tungsten.

The fourth contact plugs 290 may be disposed on the second gate structure 250. The fourth contact plugs 290 may be connected to the channel structures 230, respectively. For example, the fourth contact plugs 290 may extend through the interlayer insulating layer IL, and may be connected to the channel structures 230, respectively. The fourth contact plugs 290 may each have a fourth height “h4”. The fourth height “h4” may be substantially the same as or different from the second height “h2” or the third height “h3”. For example, the second height “h2”, the third height “h3”, and the fourth height “h4” may be substantially the same. Accordingly, the fourth contact plugs 290 may be formed when the second contact plugs 270 or the third contact plugs 280 are formed. The fourth contact plugs 290 may include a conductive material, such as tungsten.

According to the aforementioned structure, the second pads P2, the upper surfaces of the first contact plugs 260, and the upper surfaces of the channel structures 230 may be disposed substantially at the same level. That is, the fourth heights “h4” of the second contact plugs 270 that are connected to the second pads P2, the third contact plugs 280 that are connected to the first contact plugs 260, and the fourth contact plugs 290 that are connected to the channel structures 230 may be substantially the same. Accordingly, in an embodiment, the second contact plugs 270, the third contact plugs 280, and the fourth contact plugs 290 can have reduced aspect ratios, and can have a uniform depth.

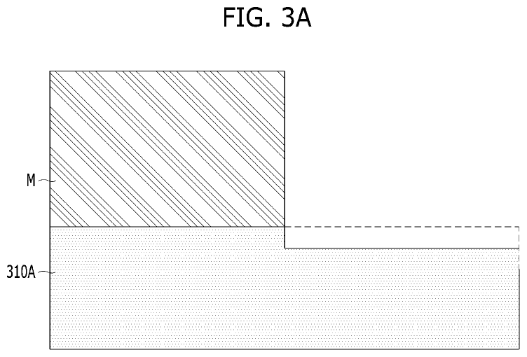

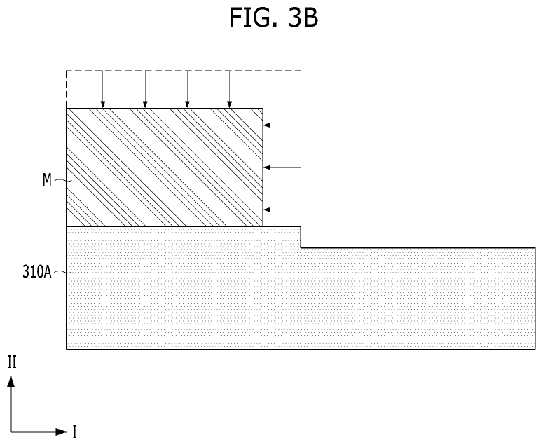

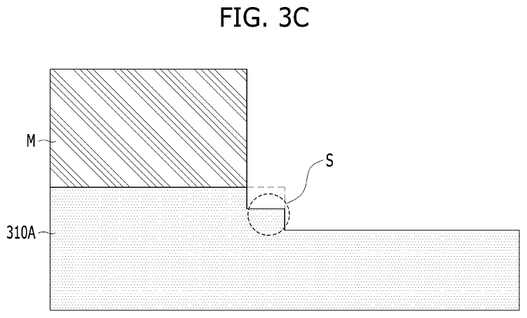

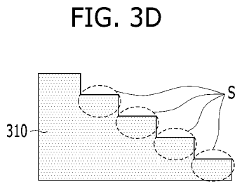

FIGS. 3A to 3D are diagrams for describing a method of manufacturing a semiconductor device according to an embodiment of the present disclosure. Hereinafter, contents that are redundant with the aforementioned contents are omitted and not described.

Referring to FIGS. 3A to 3D, a preliminary supporter 310A may be formed. The preliminary supporter 310A may include an insulating material or a conductive material or may include the insulating material or the conductive material in combination. For example, the preliminary supporter 310A may be a separate layer that is formed on a substrate. The preliminary supporter 310A may be a single layer that includes an insulating material or a conductive material. For example, the preliminary supporter 310A may be a substrate.

Next, a mask M may be formed on the preliminary supporter 310A. The mask M may include a photoresist. A part of the preliminary supporter 310A may be etched by using the mask M as an etch barrier.

Next, the mask M may be reduced. In this case, the mask M may be reduced in a first direction I or a second direction II that intersects the first direction I. For example, the mask M may be simultaneously reduced in the first direction I and the second direction II, or may be reduced in the first direction I. Next, a stair S may be formed by etching the preliminary supporter 310A again by using the reduced mask M as an etch barrier.

Next, a supporter 310 that includes a plurality of stairs S may be formed by repeating the process of forming the stair S. In this case, the stairs S of the supporter 310 may be changed depending on an etch condition. For example, a form of the stair S may be changed by adjusting the time taken to perform the etching process. When the process of forming the stair S is repeated, the stairs S that have substantially the same height may be formed by substantially identically setting an etching time.

According to the aforementioned process, the supporter 310 including the plurality of stairs S may be formed by repeating the process of etching the preliminary supporter 310A by using the mask M.

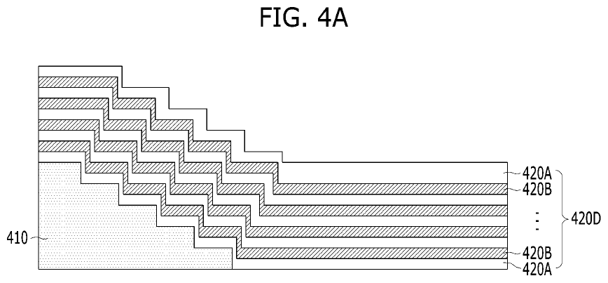

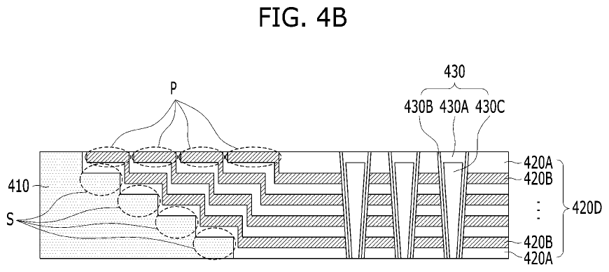

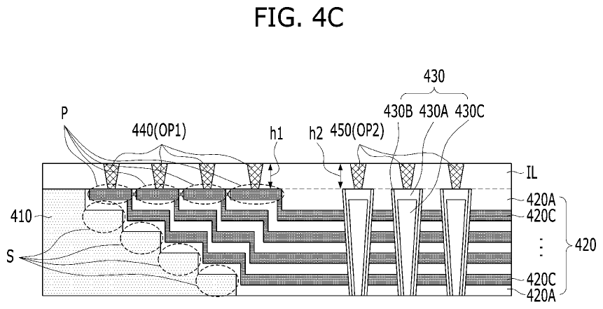

FIGS. 4A to 4C are diagrams for describing a method of manufacturing a semiconductor device according to an embodiment of the present disclosure. Hereinafter, contents that are redundant with the aforementioned contents are omitted and not described.

Referring to FIGS. 4A to 4C, a supporter 410 may be formed. The supporter 410 may be formed by repeating the process of etching the preliminary supporter 310A as described with reference to FIGS. 3A to 3D, but the present disclosure is not limited thereto. The supporter 410 including a plurality of stairs S may be formed through various manufacturing methods.

Next, a stack 420D may be formed on the supporter 410. The stack 420D may include first material layers 420A and second material layers 420B that are alternately stacked. The second material layers 420B may include pads P. For example, the first material layers 420A may include an insulating material, such as oxide, and the second material layers 420B may include a sacrificial material, such as nitride. As another example, the first material layers 420A may include an insulating material, such as oxide, and the second material layers 420B may include a conductive material, such as polysilicon, tungsten, or molybdenum.

Next, the second material layers 420B may be exposed by etching the stack 420D. For example, the stack 420D may be planarized so that each of the second material layers 420B is exposed to an upper surface of the stack 420D. The planarization process may be performed by a chemical mechanical polishing (CMP) method. A portion that belongs to each of the second material layers 420B and that is exposed through the upper surface of the stack 420D may be defined as the pad P. The pads P may be formed on the upper surface of the stack 420D. Accordingly, the pads P may be formed over the stairs S, respectively, and may be formed substantially at the same level.

Next, channel structures 430 that extend through the stack 420D may be formed. For example, although not illustrated in the drawings, the channel structures 430 may extend through the stack 420D, and may be connected to the substrate 110. In this case, the substrate 110 may include a source structure or may include a source area doped with impurities. Upper surfaces of the channel structures 430 may be disposed substantially at the same level as the upper surface of the stack 420D. For example, the upper surfaces of the channel structures 430 may be disposed substantially at the same level as upper surfaces of the pads P. The channel structures 430 may include channel layers 430A, respectively. The channel structures 430 may include memory layers 430B that surround the channel layers 430A or insulating cores 430C within the channel layers 430A, respectively, or may include the memory layers 430B or the insulating cores 430C in combination.

The second material layers 420B may be substituted with third material layers 420C. If the second material layers 420B are sacrificial layers, a slit that penetrates the stack 420D may be formed. The second material layers 420B may be removed through the slit. Next, the third material layers 420C may be formed in areas from which the second material layers 420B have been removed. The third material layers 420C may be conductive layers, and may include a conductive material, such as polysilicon, tungsten, or molybdenum.

Accordingly, a gate structure 420 including the first material layers 420A and the third material layers 420C that are alternately stacked may be formed. In this case, the third material layers 420C may each be a gate line, and the third material layers 420C may include the pads P, respectively. The pads P may be formed on an upper surface of the gate structure 420.

For reference, if the second material layers 420B include a conductive material, the substitution process may be omitted. Alternatively, a process for reducing resistance of the second material layers 420B, such as a silicidation process, instead of removing the second material layers 420B may be performed. In such a case, the second material layers 420B may each be a gate line, and the stack 420D may be the gate structure 420.

Next, first contact plugs 440 that are connected to the pads P, respectively, may be formed. First, an interlayer insulating layer IL may be formed on the gate structure 420. Next, first openings OP1 that extend through the interlayer insulating layer IL may be formed. The first openings OP1 may expose the third material layers 420C. For example, the first openings OP1 may expose the pads P. The first openings OP1 may each have a first height “h1”. The first heights “h1” of the first openings OP1 may be substantially the same because the first openings OP1 are formed to expose the pads P that are formed substantially at the same level. The aspect ratio of the first openings OP1 can be reduced because the pads P are formed on the upper surface of the gate structure 420. Accordingly, in an embodiment, a failure in a process, which occurs when the first openings having a great aspect ratio are formed, can be prevented or reduced. Next, the first contact plugs 440 may be formed within the first openings OP1, respectively. The first contact plugs 440 may include a conductive material, such as tungsten.

Second contact plugs 450 that are connected to the channel structures 430, respectively, may be formed. First, second openings OP2 that extend through the interlayer insulating layer IL may be formed. Next, the second openings OP2 may expose the channel structures 430. Next, the second contact plugs 450 may be formed within the second openings OP2. The second openings OP2 may each have a second height “h2”. The second heights “h2” may be substantially the same. Furthermore, the second height “h2” may be substantially the same as the first height “h1”.

When the first contact plugs 440 are formed, the second contact plugs 450 may be formed. In other words, when the first openings OP1 are formed, the second openings OP2 may be formed. When the first contact plugs 440 are formed within the first openings OP1, the second contact plugs 450 may be formed within the second openings OP2. Accordingly, in an embodiment, a process of manufacturing the second openings OP2 can be simplified.

According to the aforementioned process, the pads P may be formed on the supporter 410. The pads P may be formed substantially at the same level. Accordingly, in an embodiment, the aspect ratio of the first openings OP1 that are connected to the pads P can be reduced, and the first openings OP1 can have a uniform depth. Accordingly, in an embodiment, a manufacturing process for forming the first contact plugs 440 can be simplified.

Furthermore, in an embodiment, a manufacturing process for forming the second contact plugs 450 can be simplified because the second contact plugs 450 that are connected to the channel structures 430 can be formed when the first contact plugs 440 are formed.

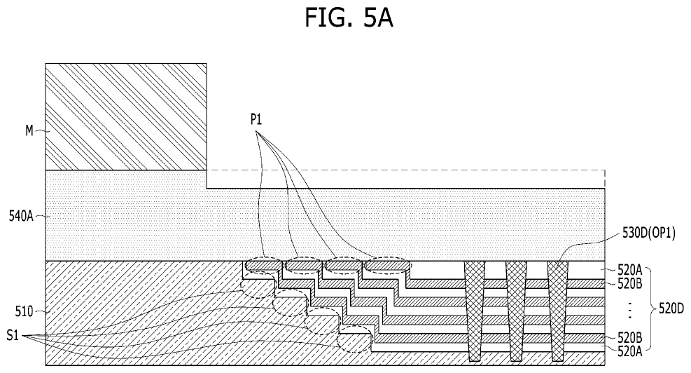

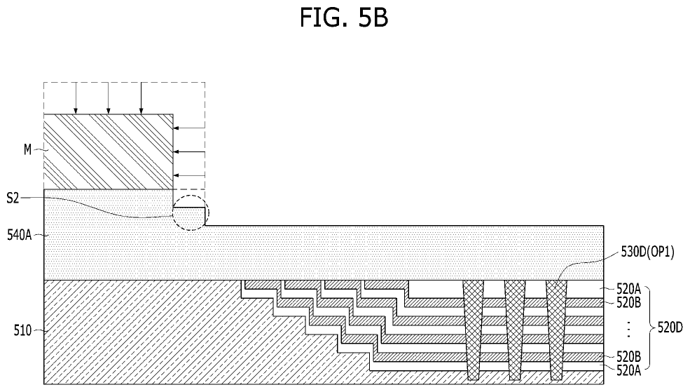

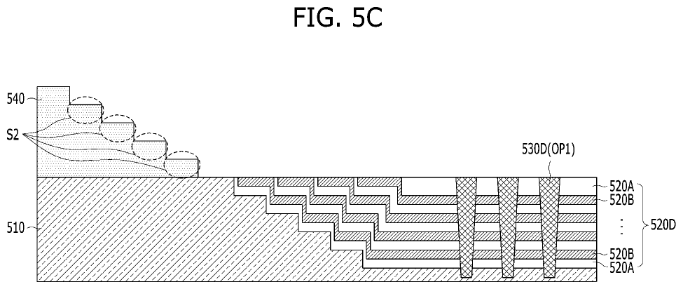

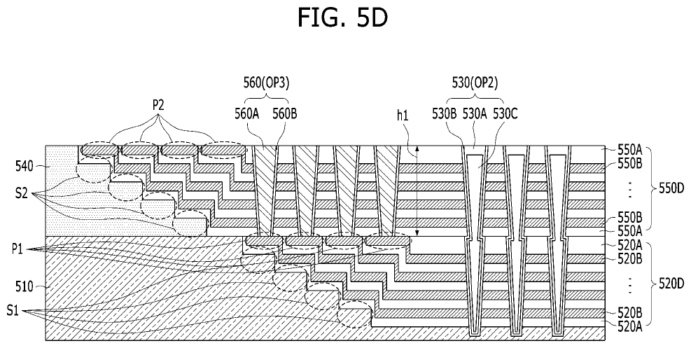

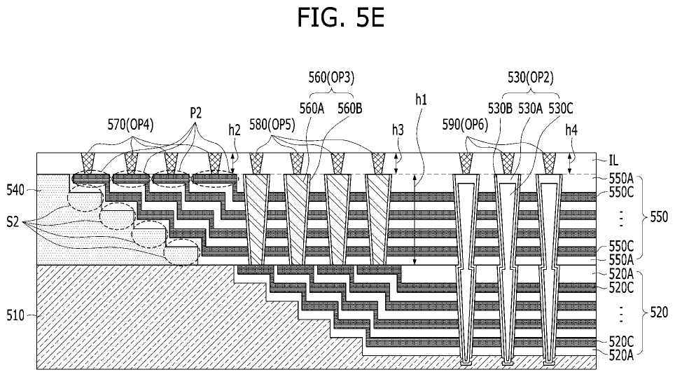

FIGS. 5A to 5E are diagrams for describing a method of manufacturing a semiconductor device according to an embodiment of the present disclosure. Hereinafter, contents that are redundant with the aforementioned contents are omitted and not described.

Referring to FIGS. 5A to 5E, a first supporter 510 may be formed. First, a first preliminary supporter may be formed. Next, the first supporter 510 including a plurality of first stairs S1 may be formed by etching the first preliminary supporter. In this case, the first preliminary supporter may be a separate layer that is formed on a substrate. Furthermore, the first preliminary supporter may be a single layer that includes an insulating material or a conductive material. For example, the first preliminary supporter may be a substrate. Accordingly, the first supporter 510 may be a part of the substrate. In this case, the substrate may include a source structure, or may include a source area doped with impurities.

Next, a first stack 520D may be formed on the first supporter 510. The first stack 520D may include first material layers 520A and second material layers 520B that are alternately stacked. The second material layers 520B may include first pads P1. The first material layers 520A may include an insulating material, such as oxide. The second material layers 520B may include a sacrificial material, such as nitride, or may include a conductive material, such as polysilicon, tungsten, or molybdenum.

Next, the second material layers 520B may be exposed by etching the first stack 520D. For example, the first stack 520D may be planarized so that each of the second material layers 520B is exposed to an upper surface of the first stack 520D. A portion that belongs to each of the second material layers 520B and that is exposed through the upper surface of the first stack 520D may be defined as the first pad P1. The first pads P1 may be formed over the first stairs S1, respectively, and may be formed substantially at the same level.

Next, sacrificial layers 530D that extend through the first stack 520D may be formed. First, first openings OP1 that extend through the first stack 520D may be formed. In this case, the first openings OP1 may each penetrate a part of the first supporter 510. Next, the sacrificial layers 530D may be formed within the first openings OP1, respectively.

Next, a second supporter 540 may be formed on the first supporter 510. The second supporter 540 may be formed by repeating a process of etching a second preliminary supporter 540A as described with reference to FIGS. 3A to 3D, but the present disclosure is not limited thereto. The second supporter 540 including a plurality of second stairs S2 may be formed through various manufacturing methods.

Next, a second stack 550D may be formed on the second supporter 540. The second stack 550D may include third material layers 550A and fourth material layers 550B that are alternately stacked. The fourth material layers 550B may include second pads P2, respectively. The third material layers 550A may include an insulating material, such as oxide. The fourth material layers 550B may include a sacrificial material, such as nitride, or may include a conductive material, such as polysilicon, tungsten, or molybdenum. Next, the fourth material layers 550B may each be exposed by etching the second stack 550D. A portion that belongs to each of the fourth material layers 550B and that is exposed through an upper surface of the second stack 550D may be defined as the second pad P2. The second pads P2 may be formed over the second stairs S2, respectively, and may be formed substantially at the same level.

Next, channel structures 530 may be formed. First, second openings OP2 that extend through the second stack 550D and that expose the sacrificial layers 530D may be formed. Next, the sacrificial layers 530D may be removed through the second openings OP2. Next, the channel structures 530 may be formed within the second openings OP2, respectively. The channel structures 530D may each include a channel layer 530A, a memory layer 530B that surrounds the channel layer 530A, or an insulating core 530C within the channel layer 530A, or may each include the channel layer 530A, the memory layer 530B, or the insulating core 530C in combination.

Next, first contact plugs 560 may be formed. First, third openings OP3 that extend through the second stack 550D and that expose the first pads P1 may be formed. The third openings OP3 may be formed when the second openings OP2 are formed. The third openings OP3 may each have a first height “h1”. The first heights “h1” of the third openings OP3 may be substantially the same. Accordingly, in an embodiment, the aspect ratio of the third openings OP3 can be reduced because the first pads P1 are formed on an upper surface of a first gate structure 520.

Next, an insulating spacer 560B may be formed within each of the third openings OP3. Next, conductive plugs 560A may be formed within the third openings OP3, respectively. Accordingly, the first contact plug 560 including the conductive plug 560A and the insulating spacer 560B may be formed. The conductive plugs 560A may be electrically connected to the first pads P1. The insulating spacer 560B may include an insulating material, such as oxide, nitride, or an air gap. In an embodiment, the insulating spacer 560B may be for preventing the fourth material layers 550B and the conductive plugs 560A from being electrically connected or for reducing an electrical connection between the fourth material layers 550B and the conductive plugs 560A.

The second material layers 520B may be substituted with fifth material layers 520C. The fourth material layers 550B may be substituted with sixth material layers 550C. If the second material layers 520B and the fourth material layers 550B are sacrificial layers, a slit that penetrate the second stack 550D and the first stack 520D may be formed. The second material layers 520B and the fourth material layers 550B may be removed through the slit. Next, the fifth material layers 520C and the sixth material layers 550C may be formed in areas from which the second material layers 520B and the fourth material layers 550B have been removed, respectively. The fifth material layers 520C and the sixth material layers 550C may each be a conductive layer, and may include a conductive material, such as polysilicon, tungsten, or molybdenum.

Accordingly, the first gate structure 520 including the first material layers 520A and the fifth material layers 520C that are alternately stacked may be formed. A second gate structure 550 including the third material layers 550A and the sixth material layers 550C that are alternately stacked may be formed. In this case, the fifth material layers 520C may include the first pads P1, respectively, and the sixth material layers 550C may include the second pads P2, respectively. The first pads P1 may be formed on the upper surface of the first gate structure 520. The second pads P2 may be formed on an upper surface of the second gate structure 550.

For reference, if the second material layers 520B and the fourth material layers 550B include a conductive material, the substitution process may be omitted. Alternatively, a process for reducing resistance of the second material layers 520B and the fourth material layers 550B, such as a silicidation process, instead of removing the second material layers 520B and the fourth material layers 550B may be performed. In such a case, the second material layers 520B and the fourth material layers 550B may each be a gate line. Furthermore, the first stack 520D may be the first gate structure 520, and the second stack 550D may be the second gate structure 550.

Next, second contact plugs 570 that are connected to the second pads P2 may be formed. First, fourth openings OP4 that expose the second pads P2 may be formed through the interlayer insulating layer IL. The fourth openings OP4 may each have a second height “h2”. The second heights “h2” of the fourth openings OP4 may be substantially the same because the fourth openings OP4 are formed to expose the second pads P2 that are formed substantially at the same level. The aspect ratio of the fourth openings OP4 can be reduced because the second pads P2 are formed on the upper surface of the second gate structure 550. Next, the second contact plugs 570 may be formed within the fourth openings OP4.

Third contact plugs 580 that are connected to the first contact plugs 560 may be formed. First, fifth openings OP5 that expose the first contact plugs 560 may be formed. The fifth openings OP5 may be formed when the fourth openings OP4 are formed. The fifth openings OP5 may each have a third height “h3”. The third heights “h3” may be substantially the same. Next, the third contact plugs 580 may be formed within the fifth openings OP5.

Fourth contact plugs 590 that are connected to the channel structures 530 may be formed. First, sixth openings OP6 that expose the channel structures 530 may be formed. The sixth openings OP6 may be formed when the fourth openings OP4 or the fifth openings OP5 are formed. The sixth openings OP6 may each have a fourth height “h4”. The fourth heights “h4” may be substantially the same. Next, the fourth contact plugs 590 may be formed within the sixth openings OP6.

According to the aforementioned process, in an embodiment, the aspect ratios of the third openings OP3 and the fourth openings OP4 can be reduced. In an embodiment, the third openings OP3 can have a uniform depth, and the fourth openings OP4 can have a uniform depth.

Furthermore, in an embodiment, a manufacturing process can be simplified because the third openings OP3 can be simultaneously formed when the second openings OP2 are formed and the fifth openings OP5 and the sixth openings OP6 can be simultaneously formed when the fourth openings OP4 are formed.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A semiconductor device comprising:
a supporter comprising a plurality of stairs;
a gate structure comprising gate lines that are stacked on the supporter, wherein the gate lines comprise pads, respectively, and the pads are disposed over the plurality of stairs, respectively;
first contact plugs that are connected to the pads, respectively; and
channel structures that extend through the gate structure.

2. The semiconductor device of claim 1, wherein the pads are disposed substantially at a same level.

3. The semiconductor device of claim 1, wherein the pads are disposed on an upper surface of the gate structure.

4. The semiconductor device of claim 1, wherein upper surfaces of the pads are disposed at a level substantially the same as a level of upper surfaces of the channel structures.

5. The semiconductor device of claim 1, wherein heights of the first contact plugs are substantially the same with each other.

6. The semiconductor device of claim 1, further comprising second contact plugs that are connected to the channel structures, respectively.

7. The semiconductor device of claim 6, wherein the first contact plugs have a height that is substantially the same as a height of the second contact plugs.

8. The semiconductor device of claim 1, wherein the supporter comprises one of an insulating material, a conductive material, and a combination of the insulating material and the conductive material.

9. The semiconductor device of claim 1, wherein the supporter is a part of the substrate.

10. A semiconductor device comprising:
a first supporter comprising a plurality of first stairs;
a second supporter disposed on the first supporter and comprising a plurality of second stairs;
a first gate structure comprising first gate lines that are stacked on the first supporter, wherein the first gate lines comprise first pads, respectively, and the first pads are disposed over the first stairs, respectively;
a second gate structure comprising second gate lines that are stacked on the second supporter, wherein the second gate lines comprise second pads, respectively, and the second pads are disposed over the second stairs, respectively;
first contact plugs that extend through the second gate structure and that are connected to the first pads, respectively; and
second contact plugs that are connected to the second pads, respectively.

11. The semiconductor device of claim 10, further comprising third contact plugs that are connected to the first contact plugs, respectively.

12. The semiconductor device of claim 11, further comprising channel structures that extend through the second gate structure and the first gate structure.

13. The semiconductor device of claim 12, further comprising fourth contact plugs that are connected to the channel structures, respectively.

14. The semiconductor device of claim 13, wherein the second contact plugs, the third contact plugs, and the fourth contact plugs have substantially a same height.

15. The semiconductor device of claim 12, wherein the first contact plugs are disposed between the second pads and the channel structures.

16. The semiconductor device of claim 10, wherein the first pads are disposed substantially at a same level.

17. The semiconductor device of claim 10, wherein the second pads are disposed substantially at a same level.

18. The semiconductor device of claim 10, wherein the first supporter and the second supporter comprise one of an insulating material, conductive material, a combination of the insulating material and the conductive material.

19. The semiconductor device of claim 10, wherein the first supporter is a part of the substrate.
